(19) United States
(12) Patent Application Publication
(10) Pub. No.: US 2026/0011605 A1
(43) Pub. Date: Jan. 8, 2026

(54) METHOD FOR PRODUCING CONDUCTIVE LINES IN AN INTERCONNECT STRUCTURE OF A SEMICONDUCTOR CHIP

(71) Applicant: IMEC VZW, Leuven (BE)

(72) Inventors: Anshul Gupta, Leuven (BE); Zsolt Tokei, Leuven (BE); Stefan Decoster, Bertem (BE); Gilles Delie, Tildonk (BE); Souvik Kundu, Kessel Lo (BE)

(21) Appl. No.: 19/255,372

(22) Filed: Jun. 30, 2025

(30) Foreign Application Priority Data
Jul. 2, 2024 (EP) 24186142.6

(51) Int. Cl. H01L 21/768; H01L 21/033; H01L 21/3213; H01L 23/522; H01L 23/528; H01L 23/532

(52) U.S. Cl. CPC H01L 21/76897; H01L 21/0332; H01L 21/0337; H01L 21/32139; H01L 21/76837; H01L 21/76877; H01L 23/5222; H01L 23/5226; H01L 23/5228; H01L 23/528; H01L 23/53257

(57) ABSTRACT

A method is disclosed for producing an array of parallel conductive lines in a first level of a multilevel interconnect structure of a semiconductor component. The lines are produced by direct etching (a conductive layer is produced), a hardmask line pattern is formed on the conductive layer and the line pattern is transferred to the conductive layer by etching the conductive layer relative to the hardmask lines. The hardmask lines are reduced in width prior to the pattern transfer. The width reduction is done at intended via locations. Local hardmask pillars are produced on the hardmask lines prior to the width reduction step, so that the original line width is maintained at the intended via locations. As a result, the width of the conductive lines obtained after the pattern transfer is smaller compared to conventional configurations, except in local areas corresponding to the locations of interconnect vias.

### CROSS-REFERENCE TO RELATED APPLICATIONS

The present application is a non-provisional patent application claiming priority to European Patent Application No. 24186142.6, filed Jul. 2, 2024, the contents of which are hereby incorporated by reference.

### FIELD OF THE DISCLOSURE

The present disclosure is related to semiconductor processing, in particular to the formation of line-shaped conductors of a multi-level interconnect structure of a semiconductor chip.

### BACKGROUND

Semiconductor-based integrated circuits continue to evolve towards smaller and smaller dimensions, leading to ongoing processing challenges. Multilayer conductive structures are typically built as layers of conductive lines, with interconnect vias formed between lines of the respective layers. As dimensions shrink, the limitations of lithography and etch processes such as dual damascene processing have become apparent.

In particular at the deepest levels of the multilayer structure, dual damascene has been increasingly replaced by direct metal etch techniques for producing parallel conductive lines. In direct metal etching, a pattern of parallel hardmask lines is formed on a metal layer and thereafter the pattern of the hardmask lines is transferred to the underlying metal. The technique also provides the formation of via connections which are self-aligned to the conductive lines, for example by locally removing the hardmask lines to create via openings and thereafter filling the openings with metal.

At low values of the conductive line pitch, in the order of a few tens of nanometres or lower, high electrical leakage of the line array has been measured. This has been attributed to line-line shorting between neighbouring lines, which may be due to a number of reasons, including incomplete metal etching, remaining metal residues between the lines, or the oxidation of the hardmask lines. The oxide formation may bridge the gap between neighbouring hardmask lines and lead to line-line shorting when the hardmask lines contain a conductive metallic component.

### SUMMARY

The disclosure aims to resolve or reduce the problems indicated hereabove. The disclosure herein includes a method for producing an array of parallel conductive lines in a first level of a multilevel interconnect structure of a semiconductor component. The “first level” does not refer necessarily to the deepest level of the interconnect structure, but it can refer to any level within the structure that has a second level above the first level. The term “conductive” may refer to “electrically conductive”.

The lines are produced by direct etching, i.e. a conductive layer is produced, a hardmask line pattern is formed on the conductive layer and the line pattern is transferred to the conductive layer by etching the conductive layer relative to the hardmask lines. However, contrary to conventional methods, the hardmask lines are reduced in width prior to the pattern transfer. The width reduction is however not done across the full line width of every line, but rather at intended via locations. Local hardmask pillars are produced on the hardmask lines prior to the width reduction step, so that the original line width is maintained at the intended via locations. As a result, the width of the conductive lines obtained after the pattern transfer is smaller compared to conventional configurations, except in local areas corresponding to the locations of interconnect vias. The smaller width implies an increased distance between adjacent lines, which may be useful in reducing the risk of line-line shorting issues.

The disclosure thereby provides (e.g., enables) reducing at least some of the causes of leakage-related problems, especially at the deeper levels of the interconnect structure, while maintaining suitable resistance values of the interconnect vias.

The disclosure provides a method for producing an array of parallel conductive lines in a first and second level of a multilevel interconnect structure of a semiconductor component. The method includes: providing a substrate comprising a planar surface formed primarily of dielectric material; producing on the planar surface a layer of electrically conductive material; producing a hardmask pattern in the form of parallel lines on the layer of conductive material; and producing at least one local hardmask pillar that fully overlaps at least one of the parallel hardmask lines, at an intended location of an interconnect via for connecting a conductive line in the first level to a conductive line in a second level directly above the first level. The method also includes reducing the width of the parallel hardmask lines except at the location of the at least one local hardmask pillar, and removing the at least one local hardmask pillar, leaving a modified hardmask line pattern comprising hardmask lines which are wider at the location or locations at which the at least one hardmask pillar was present, than outside the pillar location or locations. The method further includes transferring the modified hardmask line pattern to the layer of conductive material by etching, thereby obtaining parallel conductive lines, at least one of the lines comprising one or more local line portions having a higher width than the line width outside the local line portions. The method also includes producing dielectric material between the conductive lines and planarizing the dielectric material and the hardmask line pattern to a common planar surface, removing the material of the hardmask lines at the intended one or more via locations, to thereby obtain one or more via openings in the common planar surface, exposing one or more conductive lines of the first level at the bottom of the respective one or more via openings, filling the one or more via openings with a conductive material to thereby obtain one or more interconnect vias suitable for connecting the conductive lines of the first level to conductive lines of the second level, and producing the conductive lines of the second level, at least some of which are connected to conductive lines of the first level by one or more of the interconnect vias.

Reducing the width of the hardmask lines includes oxidizing the hardmask lines so that in an outer layer of the hardmask lines, the hardmask material is replaced by an oxide layer, and removing the oxide layer by etching the oxide layer selectively with respect to the hardmask material of the hardmask lines.

The layer of conductive material has a bottom layer, an etch stop layer directly on the bottom layer and a top layer directly on the etch stop layer. The etch stop layer stops an etch process applied for transferring the hardmask line pattern to the top layer. After transferring the hardmask line pattern to the top layer, the line pattern is further transferred by etching to the etch stop layer itself and to the bottom layer.

The first and second level of the multilevel interconnect structure belong to the three deepest levels of the interconnect structure.

The layer of conductive material comprises (e.g., or consists of) Ru, Wo or Mo and wherein the hardmask material used for forming the parallel hardmask lines is SiN or SiO₂.

The disclosure also includes a semiconductor component comprising a multilevel interconnect structure, including a first level and a second level. Each level includes an array of parallel conductive lines and one or more interconnect vias connecting conductive lines of the first level to conductive lines of the second level. The semiconductor component comprises at least one of the conductive lines of the first level comprises one or more local line portions having a higher width than the line width outside the local line portions, and wherein one or more of the interconnect vias are located at the locations of the local line portions. The interconnect vias are provided (e.g., defined) by a width in the direction perpendicular to the conductive line and by a length in the longitudinal direction of the line. The via width is (e.g., substantially) equal to and aligned to the width of the local line portions, and the via length is at least equal to the length of the local line portions.

According to an example embodiment of a semiconductor component according to the disclosure, the first and second level of the multilevel interconnect structure belong to the three deepest levels of the interconnect structure.

### BRIEF DESCRIPTION OF THE FIGURES

The above, as well as additional, features will be better understood through the following illustrative and non-limiting detailed description of example embodiments, with reference to the appended drawings.

FIGS. 1, 2, 3, 4, 5, 6, 7, 8, 9a, 9b, 10a, and 10b illustrate a process flow representative of an example embodiment of the method according to the present disclosure.

FIGS. 11, 12, 13, 14, and 15 illustrate an alternative example embodiment of the method according to the present disclosure.

FIG. 16 visualizes the characteristic features of an interconnect structure in a semiconductor component according to an embodiment of the present disclosure.

All the figures are schematic, not necessarily to scale, and generally only show parts which are necessary to elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein; rather, these embodiments are provided by way of example. Furthermore, like numbers refer to the same or similar elements or components throughout.

An example embodiment of the method of the present disclosure will now be described in detail. Any reference to material choices and dimensions is included by way of example only and does not limit the scope of the disclosure.

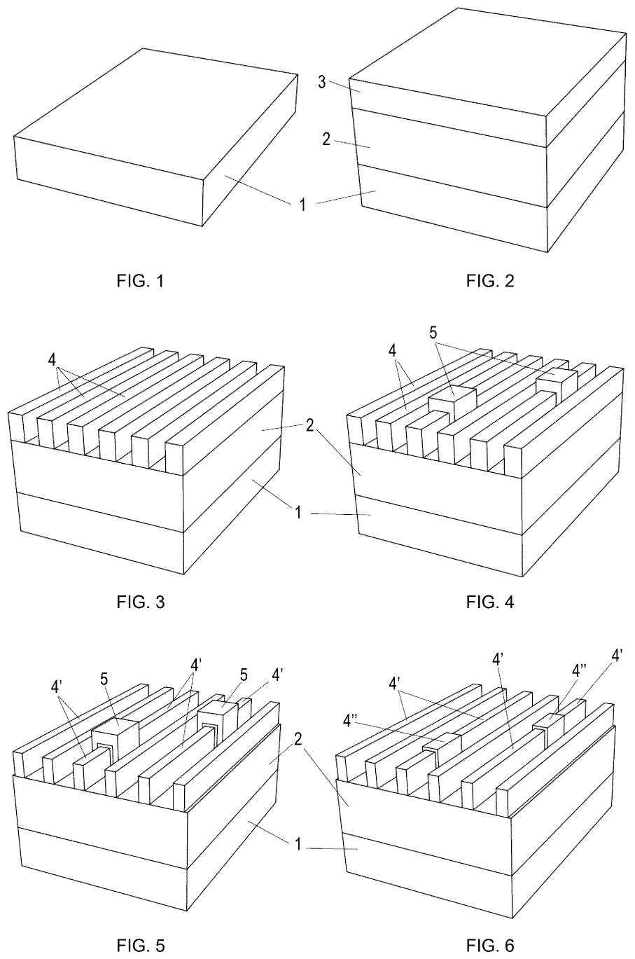

FIG. 1 shows a (e.g., small) section of a substrate 1, which may be a nano-sized upper slice of a silicon process wafer after the front end of line (FEOL) processing. In semiconductor processing, the FEOL process may constitute a sequence of processing steps for producing large numbers of semiconductor devices such as transistors and diodes (e.g., on a silicon wafer), according to the layout of several integrated circuit chips. BEOL processing adds a multi-level interconnect structure on top of the FEOL portion of the chips, the interconnect structure comprising multiple levels of electrically conductive lines, interconnected according to a predefined interconnection scheme by vertical interconnects, referred to in the present description as “interconnect vias.” The interconnect levels may be labelled Metal0, Metal1, Metal2, etc. (in short M0, M1, M2, etc.), as the line and via material may be a metal, such as Ru or W for the deepest levels and Cu for the higher levels. The deepest level M0 includes connections in direct contact with the active devices in the FEOL portion and is also referred to as the Middle of Line portion (MOL) of an integrated circuit.

The top surface of the substrate 1 may be (e.g., primarily) formed of a dielectric material, for example SiO₂ or low-K dielectric. The conductive lines of interconnect level M0 may be formed on the surface. Embedded in the dielectric layer are electrical conductors or contacts (not shown), connected for example to source or drain electrodes of transistors of the FEOL portion.

The example embodiment is related to the formation of conductive lines of level M0 and to interconnect vias for connecting the lines to the level M1; however, the same method is applicable for forming conductive lines of any level (e.g., Mi) and interconnect vias towards the lines of level Mi+1 for i=0, 1, 2, 3, etc.

Two layers are produced on the planarized top surface of the substrate 1 (e.g., base portion), as illustrated in FIG. 1. The first layer 2 is an electrically conductive layer, which may be formed of a metal. For the deep levels of the BEOL (for example i=0 to 3), this may for example be a layer of Ru, W, or Mo. Some materials, such as for Ru, may have (e.g., require) a conductive adhesion layer, such as a thin titanium nitride (TiN) layer between the substrate 1 and the Ru layer 2. Such an adhesion layer is however not shown in the illustrated example herein. The thickness of the conductive layer 2 may be in the order of 25-30 nm in the example drawings, but this thickness may be higher, for example up to 60 nm.

On top of the conductive layer 2, a layer 3 of hardmask material is formed. A thin TiN adhesion layer (not shown) may again be provided between the conductive layer 2 and the layer 3.

With reference to FIG. 3, the layer 3 of hardmask material is (e.g., then) patterned according to a parallel line pattern formed of hardmask lines 4 of (e.g., substantially) equal width. For example, the method is described hereafter for line widths of the lines 4 of about 9 nm; however, the lines 4 may have any practicably applicable line width. In this example embodiment, the width of the trenches between adjacent lines is also about 9 nm, so that the pitch of the array is about 18 nm. A suitable hardmask material (e.g., for this purpose) is silicon nitride (hereafter abbreviated as SiN). Another option for the hardmask material is SiO₂. Producing the hardmask lines 4 at these small dimensions may include double or higher multiple patterning techniques or other suitable techniques. The length of the hardmask lines 4 may depend on the (e.g., particular) layout and may be in the order of several tens of micrometres for example.

The hardmask line pattern may then be transferred to the underlying metal layer 2 to obtain an array of conductive lines by direct metal etching. According to the present disclosure however, a number of process steps are performed prior to the pattern transfer.

With reference to FIG. 4, hardmask pillars 5 are produced locally at a plurality of locations. These locations are the intended locations of interconnect vias which will connect the conductive line array of level M0 to the overlying line array of level M1. In the direction perpendicular to the hardmask lines 4, the hardmask pillars 5 overlap respective hardmask lines, i.e. each pillar 5 straddles at least one hardmask line 4 in the direction perpendicular to the line. In the direction parallel to the hardmask lines 4, the length of the pillars 5 is at least the length of the respective intended interconnect vias in the intended locations, as described herein.

The hardmask material applied for the pillars 5 may be any material suitable for use at the relevant dimensions. At the deepest M0 level for example, EUV (extreme ultra-violet) lithography using a negative tone resist material may be applied, and may be applied on an SOG/SOC stack (spin-on-glass/spin-on-carbon). Any suitable lithography process may be used.

With the hardmask pillars 5 in place, shrinking of the hardmask lines 4 is performed, as illustrated in FIG. 5. For example, shrinking is performed to the extent that the width of the hardmask lines 4 is reduced by about 2 nm and the height is reduced by about 1 nm. One way of realizing this in the case of SiN hardmask lines 4 is by subjecting the lines to an oxidization step, whereby an outer layer of the SiN lines 4 of about 1 nm thick is oxidized, i.e. a 1 nm thick silicon dioxide layer replaces the outer 1 nm of SiN. Any suitable method for realizing the oxidization may be applied. For example, realizing the oxidization may include exposure during a few seconds to an oxygen-based plasma in a dry etch plasma etch tool, at room temperature and at a pressure applicable for dry etching. Other approaches are possible, such as heating under oxidizing conditions or exposure to ozone (O₃). Thereafter, the silicon dioxide is selectively removed relative to the remaining SiN, leaving the SiN lines which have shrunk on each side and at the top by about 1 nm. This may be accomplished by a dry or wet etch recipe exhibiting a suitable etch selectivity for removing silicon dioxide relative to SiN. For example, a suitable dry etching process is fluor-based reactive ion etching, and a suitable wet etching process may use a diluted HF (hydrofluoric acid) treatment.

Other suitable methods may however be applied to realize the shrinking step, depending on the material of the hardmask lines for example.

The width and height of the hardmask lines is thereby reduced, except underneath the hardmask pillars 5, i.e. at the intended locations of the interconnect vias.

With reference to FIGS. 5 and 6, the hardmask pillars 5 are stripped relative to the material of the hardmask lines 4. The result is a modified pattern of hardmask lines, having (e.g., comprising) reduced line portions 4′, having a reduced width compared to the original lines 4 of about 7 nm and a reduced height, and local non-reduced line portions 4″ at the intended via locations, where the hardmask lines have retained their original width of about 9 nm, and their original height. The non-reduced line portions 4″ are “local” in the sense that they extend on a small portion of the total line length, for example exceeding not more than about one or two percent of the total line length. Some of the lines 4 may be reduced across their full length, if no interconnect vias are intended to be placed on the lines.

The modified hardmask line pattern is now transferred to the underlying metal layer 2, as illustrated in FIG. 7, by, for example, an anisotropic etch process. This may be done by dry etching, for example reactive ion etching. Conductive lines 10 are thereby formed, having a width of about 7 nm, except at the intended via locations, where the line width is about 9 nm. The pattern transfer process may be an (e.g., essentially) anisotropic etching process wherein the material of layer 2 is removed in trenches provided (e.g., defined) by the distances between the hardmask lines. The figures show sidewalls of the conductive lines 10 that are (e.g., substantially) vertical; however, the vertical orientation may include small deviations.

The height of the conductive lines 10 corresponds to the thickness of the original conductive layer 2, i.e. about 25-30 nm in the represented case, which may imply a conductive line aspect ratio of about 4 outside the intended via locations. For example, the conductive layer 2 may have a higher thickness than 25-30 nm, and higher aspect ratios (e.g., up to 6 or 7) are achievable with lithographic and etch technology.

The hardmask lines 4′, 4″ may be shown (or discussed) as substantially retaining their original height after the pattern transfer step; however, the height of the hardmask lines may be reduced during the etch process for forming the conductive lines 10, compared to their original height, as some of the hardmask material may be consumed during etching.

Then, with reference to FIG. 8, a dielectric material 11 is deposited in the trenches between the aggregate lines, i.e. the lines formed of the conductive lines 10 and the hardmask lines 4′, 4″ on top of the conductive lines. The dielectric 11 may be any material suitable for isolating conductive lines in a BEOL structure, such as silicon dioxide or low-K materials. Depending on the material and deposition technique used, the dielectric may fill the trenches between the lines completely from the bottom up, or air gaps may be created between adjacent lines. Air gap formation at the lower end of the trenches may be used (e.g., desired) as it may improve electrical isolation between the lines and reduces the capacitance of neighbouring metal lines. The dielectric however fills the width of the trenches fully in an area near the top of the aggregate lines.

As illustrated in FIG. 8, the dielectric material is planarized to a common level with the hardmask lines 4′, 4″, resulting in a planarized surface at the common level, wherein the hardmask lines are exposed in the surface. Planarization methods, such as chemical mechanical polishing (CMP) recipes, may be applied for this purpose. The planarization removes the height difference between the non-reduced line portions 4″ and the reduced line portions 4′.

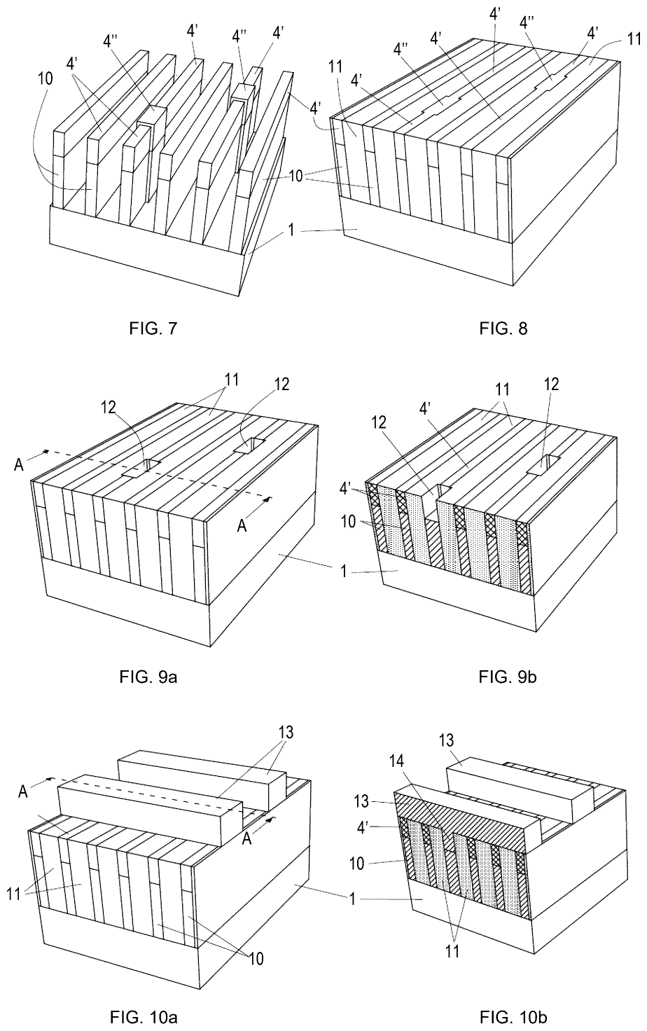

At the intended locations of the interconnect vias, the hardmask material is now locally removed in the portions (e.g., areas) 4″ where the hardmask lines have retained their original width, as illustrated in FIG. 9a and (e.g., in the 3D section view) in FIG. 9b. The section plane A-A passes through one of the via locations. The local removal of the hardmask material can be done by lithography and etching according to litho and etch recipes based on a predefined layout of the via locations. If an adhesion layer was present between the conductive layer 2 and the hardmask layer 3, this adhesion layer may also be removed locally. A number of via openings 12 are thereby created, wherein the upper surface of respective conductive lines 10 is exposed at the bottom of the via openings 12.

In the example embodiment shown, the length of the via openings 12 in the longitudinal direction of the lines 4′ is (e.g., substantially) the same as the length of the non-reduced line portions 4″, and the via openings 12 are (e.g., perfectly) aligned to the non-reduced line portions 4″ in the longitudinal direction. The via openings 12 could however be shorter and/or slightly misaligned in this longitudinal direction compared to the non-reduced line portions 4″, as long as via openings 12 are created that provide (e.g., enable) the formation of an interconnect via of sufficient length in the longitudinal direction. The width of the via openings 12 in the direction perpendicular to the lines 4′, is determined by the width of the non-reduced line portions 4″, i.e. about 9 nm, as illustrated in the drawings. In the perpendicular direction, the via openings 12 are thereby self-aligned to the width of the conductive lines 10.

The via openings 12 are filled with a conductive material in order to form interconnect vias connecting the conductive lines 10 of the M0 level to conductive lines of the M1 level. This may be done in a number of ways in terms of the materials used for the interconnect vias and the process steps used (e.g., required) for filling the openings and producing the M1 lines. Processes and materials for the via formation and M1 line formation can be applied.

For example, and with reference to FIGS. 10a and 10b, an additional metal layer may be deposited, for example a Ru layer, filling the via openings 12 and forming a blanket metal layer on the planarized surface. If Ru is used, a titanium oxide liner may, for example, be deposited first on the bottom and sidewalls of the via openings 12 and on the planarized surface, for obtaining good adhesion of the Ru. The blanket metal layer formed on the planarized surface is then patterned by direct metal etching (e.g., in the same manner as described above) to form a second array of conductive lines 13 of the M1 level arranged crosswise with respect to the lines 10 of the M0 level. The interconnect vias 14, one of which is shown in the section view in FIG. 10b, connect a line 10 in the M0 level to a crosswise arranged line 13 in the M1 level. The line 10 is narrower at the via locations than outside the via locations, due to the (e.g., above-described) shrinking of the hardmask lines 4 prior to performing the etch process that creates the conductive lines 10.

As such, the conductive lines of the M0 level are thinner and thereby placed further apart across the majority of their length (e.g., compared to conventional configurations), except at the locations of interconnect vias which connect these lines to conductive lines of the next level M1. The interconnect vias themselves are self-aligned (in the direction perpendicular to the lines 10) to the wider portions of the conductive lines 10. This is useful as it provides (e.g., ensures) that the process of filling the via openings 12 is not rendered more difficult (e.g., compared to conventional methods), and that the resistance of the interconnect vias 14 may also be the same or similar to conventional configurations.

As stated, the actual production of the interconnect vias 14 can be done in a number of ways, other than the approach referred to herein. According to another approach, the via openings are filled with a metal other than the metal of the conductive lines 10, for example, the material, W, may be used to fill the via openings when the lines 10 are formed of Ru. The vias are then planarized to a common level with the dielectric, and the M1 metal is deposited and patterned, wherein the M1 metal may be another material than the material of the vias.

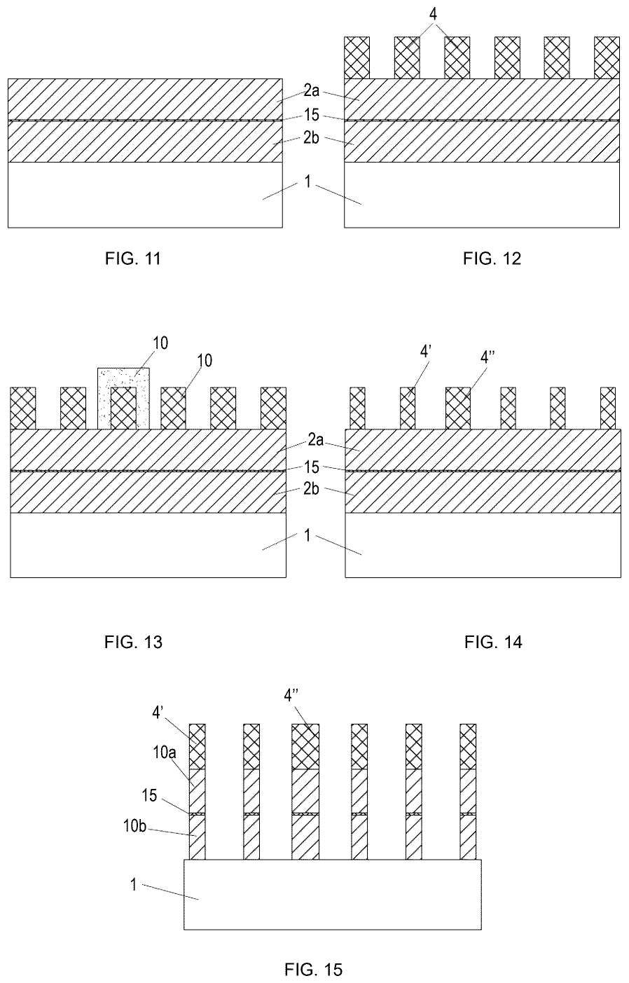

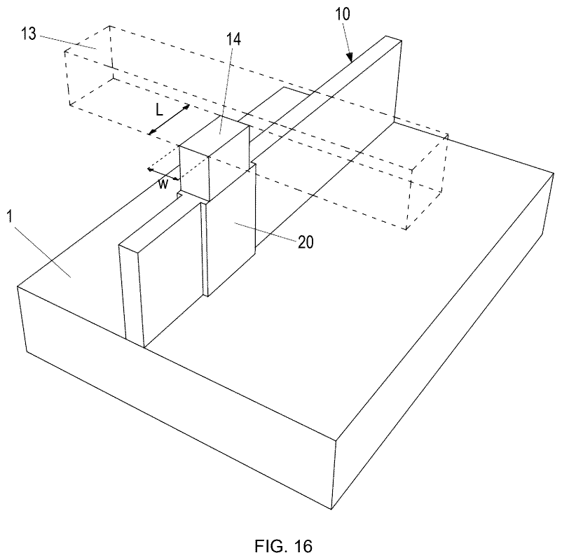

FIG. 11 illustrates an alternative example embodiment of the present disclosure. FIG. 11 is a section view of the (e.g., same) substrate portion 1 shown in FIG. 1, i.e. an upper slice of a process wafer after completion of a FEOL process flow. Instead of the integrally formed conductive layer 2 however, a first and second conductive layer 2a, 2b is formed on the substrate, with a thin electrically conductive etch stop layer 15 in between the two. The combined height of layers 2a, 2b and 15 may be about the same as the thickness of layer 2 in FIG. 2. The material of layers 2a and 2b may be the same material, for example Ru, but it is possible also to use different materials for layers 2a and 2b. The method steps may be substantially the same as in the first embodiment, while the etch stop layer 15 has an improved impact (e.g., effect) during the step of producing the conductive lines. As illustrated in FIG. 12, the formation of the hardmask line pattern including (e.g., consisting of) lines 4 takes place in the same manner as in the first example embodiment. Also, the formation of the pillars 5 and shrinking of the hardmask lines to form reduced line portions 4′ and non-reduced line portions 4″ is accomplished (e.g., done) in the same way, as illustrated in FIGS. 13 and 14. Then the hardmask pillars 5 are stripped (FIG. 15) and the modified hardmask line pattern is transferred to the underlying layers 2a, 15, 2b by etching. The etch stop function of etch stop layer 15 impacts (e.g., is relevant to) the etch process for etching layer 2a. In other words, etching layer 2a is stopped by the etch stop layer 15. Another etch recipe is then applied for removing the etch stop layer 15 itself, after which the bottom layer 2b is removed by a suitable etch recipe applicable for the material of layer 2b. The single etch process applied in the first example embodiment is therefore replaced by a three-step etch process. Depending on the applied material and thickness of the etch stop layer, this approach may reduce the number of defects caused due to sidewall attack during the direct metal etch process. When the layers 2a and 2b are formed of Ru, both having a thickness between 10 and 30 nm for example, a suitable etch stop layer 15 can be formed of TiN or W, wherein the thickness of the etch stop layer may be in the order of (e.g., about) 0.3 nm to 3 nm. The resulting conductive lines are now formed of a bottom portion 10b, a thin etch stop layer portion 15 and a top portion 10a.

A semiconductor component according to the disclosure is provided with (e.g., characterized by) a (e.g., particular) profile of the conductive lines of the BEOL interconnect levels, and the semiconductor component is produced by the method described herein. In these levels, the conductive lines include one or more local line portions having a higher width than the line width outside the local line portions. This is shown in FIG. 16, which schematically shows a single line 10 of the M0 level, a single line 13 of the M1 level and an interconnect via 14 connecting these two lines and without showing the dielectric material into which the lines are embedded. The local line portion (e.g., having a higher width than the line width outside the line portion) is indicated by numeral 20. The M1 line 13 is shown in transparent view in order to visualize the M0 line 10 and the interconnect via 14 located above the local line portion 20. The interconnect via 14 is provided (e.g., defined) by a width w in the direction perpendicular to the conductive line 10 and by a length L in the longitudinal direction of the line 10. Because the via 14 has been produced in the above-described manner, i.e. by removing material of the non-reduced hardmask portion 4″, the width w is (e.g., substantially) equal to and aligned to the width of the local line portions (i.e. the interconnect via is produced in such a manner that the via is self-aligned in the width direction). In the longitudinal line direction, the via length L is at least equal to the length of the local line portion 20. In the embodiment shown, the via length L is smaller than the length of the local line portion 20. This via length L may be determined by the mask dimensions used for producing the via openings 12 and can therefore be smaller than the length of the non-reduced hardmask portion 4″.

While the disclosure has been illustrated and described in detail in the drawings and foregoing description, such illustration and description are to be considered illustrative or examples and not restrictive. Other variations to the disclosed embodiments can be understood and effected by those skilled in the art in practicing the claimed disclosure, from a study of the drawings, the disclosure and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

What is claimed is:

1. A method for producing an array of parallel conductive lines in a first level and a second level of a multilevel interconnect structure of a semiconductor component, the method comprising:
providing a substrate comprising a planar surface formed primarily of dielectric material;
producing on the planar surface a layer of electrically conductive material;
producing a hardmask pattern in the form of parallel lines on the layer of conductive material;
producing at least one local hardmask pillar that overlaps at least one of the parallel hardmask lines, at an intended location of an interconnect via for connecting a conductive line in the first level to a conductive line in a second level directly above the first level;
reducing a width of the parallel hardmask lines except at the location of the at least one local hardmask pillar;
removing the at least one local hardmask pillar;
leaving a modified hardmask line pattern comprising hardmask lines, the hardmask lines are wider at the location at which the at least one hardmask pillar was present, than outside the pillar location;
transferring the modified hardmask line pattern to the layer of conductive material by etching, obtaining parallel conductive lines, at least one of the lines comprising one or more local line portions having a higher width than a line width outside the local line portions;
producing dielectric material between the conductive lines and planarizing the dielectric material and the hardmask line pattern to a common planar surface;
removing the material of the hardmask lines at the intended one or more via location, to obtain one or more via openings in the common planar surface;
exposing one or more conductive lines of the first level at a bottom of the one or more via openings;
filling the one or more via openings with a conductive material to obtain one or more interconnect vias suitable for connecting the conductive lines of the first level to conductive lines of the second level; and
producing the conductive lines of the second level, at least some of the conductive lines of the second level are connected to conductive lines of the first level by one or more of the interconnect vias.

2. The method according to claim 1, wherein reducing the width of the hardmask lines includes:
oxidizing the hardmask lines so that in an outer layer of the hardmask lines, the hardmask material is replaced by an oxide layer.

3. The method according to claim 2, wherein reducing the width of the hardmask lines further includes:
removing the oxide layer by etching the oxide layer selectively with respect to the hardmask material of the hardmask lines.

4. The method according to claim 1, wherein the layer of conductive material comprises a bottom layer.

5. The method according to claim 4, further comprising an etch stop layer on the bottom layer.

6. The method according to claim 5, wherein the etch stop layer is directly on the bottom layer.

7. The method according to claim 4, further comprising a top layer on the etch stop layer.

8. The method according to claim 6, wherein the top layer is directly on the etch stop layer.

9. The method according to claim 8, wherein the etch stop layer stops an etch process applied for transferring the hardmask line pattern to the top layer.

10. The method according to claim 9, wherein, after transferring the hardmask line pattern to the top layer, the line pattern is further transferred, by etching, to the etch stop layer.

11. The method according to claim 10, wherein, after transferring the hardmask line pattern to the top layer, the line pattern is further transferred, by etching, to the bottom layer.

12. The method according to claim 1, wherein the first level of the multilevel interconnect structure belongs to three levels of the interconnect structure.

13. The method according to claim 12, wherein the second level of the multilevel interconnect structure belongs to the three levels of the interconnect structure.

14. The method according to claim 13, wherein the three levels of the interconnect structure are the deepest levels of the interconnect structure.

15. The method according to claim 1, wherein the layer of conductive material comprises Ru, Wo, or Mo.

16. The method according to claim 1, wherein the hardmask material for forming the parallel hardmask lines is SiN or SiO₂.

17. A semiconductor component comprising a multilevel interconnect structure, the multilevel interconnect structure including:
a first level and a second level, each of the first level and the second level comprising an array of parallel conductive lines and one or more interconnect vias connecting conductive lines of the first level to conductive lines of the second level,
at least one of the conductive lines of the first level comprises one or more local line portions having a higher width than the line width outside the local line portions,
wherein one or more of the interconnect vias are located at locations of the local line portions, the interconnect vias have a width in a direction perpendicular to the conductive line and a length in a longitudinal direction of the line,
wherein the via width is substantially equal to and aligned to the width of the local line portions, and
wherein the via length is at least substantially equal to the length of the local line portions.

18. The component according to claim 17, wherein the first level of the multilevel interconnect structure belongs to three levels of the interconnect structure.

19. The component according to claim 18, wherein the second level of the multilevel interconnect structure belongs to the three levels of the interconnect structure.

20. The component according to claim 19, wherein the three levels are the deepest levels of the interconnect structure.
